(19) United States
(12) Patent Application Publication
(10) Pub. No.: US 2004/0009115 A1
(43) Pub. Date: Jan. 15, 2004

(54) Selective area growth of aligned carbon nanotubes on a modified catalytic surface

(76) Inventors: Thye Shen Andrew Wee, Singapore (SG); Amarsinh Gohel, Singapore (SG); Kok Chung Chin, Singapore (SG)

Correspondence Address: KLARQUIST SPARKMAN CAMPBELL LEIGH & WHINSTON, LLP, Attention: Mr. Richard J. Polley, One World Trade Center, 121 S.W. Salmon Street, Suite 1600, Portland, OR, 97204, US

(21) Appl. No.: 10/461,251

(22) Filed: Jun. 12, 2003

Related U.S. Application Data
(60) Provisional application No. 60/387,920, filed on Jun. 13, 2002.

(51) Int. Cl. C23C 16/00; B05D 3/00

(52) U.S. Cl. 423/447.3; 427/555; 427/249.1; 502/325

(57) ABSTRACT

This invention provides a method for making a catalyst for use in the preparation of carbon nanotubes, which method comprises subjecting a thin film of a catalytic metal on a support to selective mechanical or electromagnetic modification to enhance the grain size of the metal.

This invention also provides a modified thin film of a catalytic metal on a support that is useful for the selective area growth of carbon nanotubes, which modification is selective in area and is made through mechanical or electromagnetic means to enhance the grain size of the metal.

This invention also provides a process for the selective area growth of carbon nanotubes on a substrate which bears a catalyst thin film, the process comprising contacting a modified thin film catalyst defined above with a carbon source under pressure and temperature conditions which promote carbon nanotube synthesis.

This invention also provides the use of the modified surface deposited carbon nanotubes for the manufacture of display, electronic and microelectromechanical devices.

### CROSS-REFERENCE TO RELATED APPLICATION

This application claims priority to U.S. provisional application serial No. 60/387,920 filed on Jun. 13, 2002, the full disclosure of which is incorporated herein by reference.

### FIELD OF THE INVENTION

The present invention relates to carbon nanotube production.

### BACKGROUND OF THE INVENTION

Carbon nanotubes have been shown to exhibit technologically useful electrical properties. For example, they have been used to fabricate large scale field emission displays, as well as prototype nanoscale transistors and circuits (P. G. Collins et al., Science 292 (2001): 706; H. W. Ch. Postma et al., Science 293 (2001): 76; and A. Bachtold et al., Science 294 (2001): 1317). For the purpose of field emission displays (M. Chhowalla, et al., Appl. Phys. Lett. 79 (2001): 2079 and J. T. L. Thong, et al. Appl. Phys. Lett. 79 (2001): 2811), it is necessary to have well-defined areas of high quality well-aligned nanotubes. As more is understood about their growth mechanisms, novel methods to control and manipulate the growth of well-aligned carbon nanotubes have been proposed. For example, electric-field-directed growth of single-walled carbon nanotube (SWNT) and selective lateral growth of multi-walled carbon nanotube (MWNT) bridges on patterned silicon wafers have been demonstrated (T. Zhang et al., Appl. Phys. Lett. 79 (2001): 3155 and Y.S. Han et al., J. Appl. Phys. 90 (2001): 5731).

A disadvantage of most of the current methods of selective area growth of carbon nanotubes on a substrate is the complicated multi-step processing that must be used to fabricate the device. Photolithography steps are required to pattern the substrate before the growth of carbon nanotubes, which greatly increase the costs of the device. Ion lithography and focused ion beam (FIB) methods are used for sub-100 nm processing. An aim of this work is to demonstrate selective area growth of carbon nanotubes on a modified catalytic surface by modifying the catalytic substrate surface morphology using mechanical or electromagnetic means.

### SUMMARY OF THE INVENTION

In one aspect, this invention provides a method for making a catalyst for use in the preparation of carbon nanotubes, which method comprises subjecting a thin film of a catalytic metal on a support to selective mechanical or electromagnetic modification to enhance the grain size of the metal.

In another aspect, this invention provides a modified thin film of a catalytic metal on a support that is useful for the selective area growth of carbon nanotubes, which modification is selective in area and is made through mechanical or electromagnetic means to enhance the grain size of the metal.

In another aspect, this invention provides a process for the selective area growth of carbon nanotubes on a substrate which bears a catalyst thin film, the process comprising contacting a modified thin film catalyst defined above with a carbon source under pressure and temperature conditions which promote carbon nanotube synthesis.

In another aspect, this invention also provides the use of the modified surface deposited carbon nanotubes for the manufacture of display, electronic and microelectromechanical devices.

### BRIEF DESCRIPTION OF THE DRAWINGS

The present invention will be further understood from the following description with reference to the accompanying drawings, in which:

FIG. 1(a) is an atomic force microscopy (AFM) image of an unmodified Fe surface.

FIG. 1(b) is an AFM image of an Fe surface modified by 02+ion beam bombardment.

FIG. 1(c) is a graph of vertical growth of carbon nanotubes versus grain size at different temperatures.

FIG. 1(d) is a graph of density of carbon nanotubes versus grain size at different temperatures.

FIG. 2 is an SEM image of carbon nanotubes grown on an Fe surface modified using ion beam bombardment and an Fe surface that was not so modified.

FIG. 3(a) is a plot of vertical growth rate of carbon nanotubes on an Fe surface modified by ion beam bombardment and an Fe surface that was not so modified versus temperature.

FIG. 3(b) is a plot of vertical growth selectivity (derived from the vertical growth rate data presented in FIG. 3(a)) versus temperature.

FIG. 4(a) is an SEM image of an Fe surface after H₂ plasma treatment.

FIG. 4(b) is an SEM image of an Fe surface after ion beam bombardment and after H₂ plasma treatment.

FIG. 5(a) is an SEM image of an Fe surface modified by laser beam at a magnification of 5000×.

FIG. 5(b) is an SEM image of the surface of FIG. 5(a) at a magnification of 600×.

FIG. 6(a) is an SEM image of carbon nanotubes grown on the surface of FIG. 5(a) at a magnification of 5000×.

FIG. 6(b) is an SEM image of the carbon nanotubes of FIG. 6(a) at a magnification of 600×.

FIG. 7 is a scanning electron microscopy image (SEM) of carbon nanotubes grown at 630° C. on an Fe surface at a magnification of 25000×.

### DETAILED DESCRIPTION

The effect of catalytic surface morphology is an important factor in both the size and density distribution of grown carbon nanotubes (Z. F. Ren, et al., Science 282 (1998): 1105). For instance, transmission electron microscopy (TEM) studies have shown that a nanotube grows directly out of a single catalytic nanoparticle (Y. Zhang, et al., Appl. Phys. A 74 (2002): 325). By modifying the grain size and roughness of the catalytic surface, a simple process for selective area growth of nanotubes, without the need for lithography steps, is provided. This approach comprises three steps: deposition of catalyst, modification of the catalytic surface and growth of nanotubes.

“Grain size” refers to the diameter of a grain on the surface of the catalyst.

“Grain” refers to a crystal of the polycrystalline catalytic metal used in the invention.

“Roughness” is a common measure of surface morphology. The Root Mean Square (RMS) roughness is obtained from the following equation, solved by using data obtained by AFM:

$${R}_{rms} = \sqrt{\frac{{\sum }_{n = 1}^{N} {( {Z}_{n} - \overline{Z} )}^{2}}{N - 1}}$$

Zₙ is the height measurement of pixel n (wherein a pixel is the smallest discrete element of the image obtained by AFM and “n” is any given pixel)

\overline{Z} is the arithmetic mean height of pixels within a given area

N is the number of points (or pixels) within a given area

The catalyst thin film can be comprised of any metal that catalyzes the formation of carbon nanotubes. In one embodiment, the catalyst thin film comprises a metal such as Fe, Ni, Co or mixtures thereof (alloys). The thin film can have a thickness of from about 50 to about 500 nm, with a film thickness of about 50 nm being preferred. The catalyst thin film can be deposited by known methods, including evaporation techniques, RF sputtering and chemical vapour deposition (CVD). “Evaporation techniques” are a thin film deposition process utilizing evaporation (by heating) of a source material onto a substrate. “RF sputtering” or “sputtering” is a vacuum deposition process which physically removes portions of a coating material called the target, and deposits a thin, firmly bonded film onto the substrate. The process occurs by bombarding the surface of the sputtering target with gaseous ions under high voltage acceleration. As these ions collide with the target, atoms or occasionally entire molecules of the target material are ejected and propelled against the substrate, where they form a very tight bond. “Chemical vapour deposition” is a deposition process that involves depositing a solid material thin film from a gaseous phase. The precursor gases react or decompose forming a solid phase which deposits onto the substrate. RF sputtering is the preferred method.

Many substrates can be used to support the thin film catalyst. The substrate on which the catalyst thin film is deposited can be, for example, different crystal faces of silicon such as Si(100), Si(001) and Si(111), and non-silicon substrates such as alumina and graphite. The substrate is preferably planar, but it can also be non-planar as long as the metal morphology is not adversely affected; i.e., the substrate must be reasonably flat on the length scale of the grains.

The modification of a selected area of the catalyst thin film can be pursued by either mechanical or electromagnetic means. The selective mechanical or electromagnetic modification can be made to the thin film of the catalytic metal to obtain modification in a predetermined pattern. In one embodiment, mechanical means for modifying the catalyst thin film involve ion beam bombardment. In another embodiment, electromagnetic means for modifying the catalyst thin film involve laser beams. In another embodiment, a combination of means for modifying the catalyst thin film may be used.

Ion beam-induced surface roughening of metals and semiconductors is a known phenomenon. In general the surface roughens with increasing sputter depth, especially in the first 100 nm or so. “Sputter depth” or “depth” is the vertical distance between the original or unmodified surface of the catalytic metal and the modified surface. Sputter depth will typically vary from about 10 nm to about 40 nm, with a sputter depth of about 20 to 30 nm preferred and a sputter depth of 25 nm being especially preferred.

The detailed behaviour of surface roughening varies with ion species, ion energy, incident angle, substrate composition and orientation. Suitable ion beams are those which utilise ion species such as O₂⁺, liquid metal ions and noble gas ions. Liquid metal ions include Cs⁺ and Ga⁺ ions, while noble gas ions include Ar⁺, Kr⁺ and Xe⁺ ions. Ion beams that utilize O₂⁺ ions are preferred. In some instances negatively charged ions can also be used, but many negatively charged ions are reactive and thus not suitable. The ion beam energy can be varied from about 1 keV to about 30 keV, with an ion beam energy of about 7.5 keV being preferred. The ion beam energy, and the duration of bombardment, can be varied to give different sputter depths. The incidence angle of the ion beam on the thin film catalyst is not critical, but an incidence angle of from between 300 to 60° is suitable.

In one embodiment, the modification of the catalyst thin film involves the abrasion of the thin film surface, which increases the grain size of the metal. Both roughness and grain size increase with increased sputter depth within the thin film. This, in turn, influences the aligned carbon nanotube growth rate. It has been observed that growth rate increases with increasing grain size, reaches an optimum and then begins to fall. Without being bound by any theory, it is hypothesized that growth rate falls because at the large sputter depths used to provide a large grain size, the metal catalyst thins, resulting in a fall in particle density on the surface of the catalyst.

Grain size is also related to packing density. “Packing density” refers to the number of grains per unit area. The packing density of the modified surfaces of the invention decreases as grain size increases. Unmodified surfaces typically have a high packing density and hence an overall smoother morphology, which facilitates the growth of graphitic deposits that inhibit nanotube growth.

The density of aligned nanotubes follows a similar pattern as growth rate, with density increasing with increasing grain size, reaching an optimum and then beginning to fall. Density is highest at the grain size where growth rate is optimum. Density is measured by counting the number of nanotubes within a representative area.

As a result of ion beam modification, if the metal catalyst is Fe, the Fe catalyst grain size can be varied between about 15 to 70 nm, depending on the sputter depth. A grain size of about 30 to 60 nm, especially of 35 to 50 nm, is preferred with a grain size of 53 nm being especially preferred. Variation of the grain size may occur and can be explained by effects due to off-normal incidence of the 02+sputtering beam, which causes inhomogeneous oxidation leading to a rougher surface. Although ion sputtering creates a shallow crater a few tens of nanometers deep, this does not significantly affect the measurement of nanotube growth rate since the nanotubes are usually of the order of microns in length.

Suitable lasers for electromagnetic modification will be known to those of skill in the art. Preferably a solid-state laser is used, such as a Nd:YAG laser.

After the catalyst surface has been modified it may be cleaned before being used to catalyse nanotube growth. For example, it may be treated in a reducing plasma, e.g. an H₂ plasma, for a period of time, say 10 minutes, to clean and remove oxides from the catalyst surface.

Chambers in which carbon nanotubes are grown typically contain trace amounts of residual carbon. The chamber may be purged prior to use to substantially eliminate the residual carbon.

In one embodiment, the modified catalyst thin films are contacted with a carbon source under pressure and temperature conditions which promote carbon nanotube synthesis. In a preferred embodiment, multi-walled carbon nanotubes are produced.

Aligned nanotubes can be grown using a range of chemical vapour deposition (CVD) methods known in the art, for example thermal, plasma-enhanced, microwave plasma, hot-filament, and laser CVD methods. All these techniques are known variations of the CVD method. A preferred chemical vapour deposition (CVD) method is hot filament plasma enhanced chemical vapor deposition (HF-PECVD), which is further described in Ho GW, Wee ATS, Lin J, Tjiu WC, Thin Solid Films 388: (1-2) 73-77 Jun. 1, 2001, which is incorporated herein by reference. Carbon nanotube synthesis is typically carried out between temperatures of from about 700° C. to about 1000° C., and at pressures of from about 1 to about 103 mbar. However, a higher growth rate and density is observed on the modified areas of the catalyst film, facilitating selective area growth of aligned carbon nanotubes at lower temperatures, for example from about 500° C.

Acceptable carbon sources for producing carbon nanotubes include hydrocarbons, carbon monoxide and carbon dioxide. Preferred hydrocarbons include methane, ethene and acetylene. Hydrogen or an inert gas can also be present in the reaction mixture.

All publications, patents and patent applications cited in this specification are herein incorporated by reference as if each individual publication, patent or patent application were specifically and individually indicated to be incorporated by reference. The citation of any publication is for its disclosure prior to the filing date and should not be construed as an admission that the present invention is not entitled to antedate such publication by virtue of prior invention.

It must be noted that as used in this specification and the appended claims, the singular forms “a”, “an”, and “the” include plural reference unless the context clearly dictates otherwise. Unless defined otherwise all technical and scientific terms used herein have the same meaning as commonly understood to one of ordinary skill in the art to which this invention belongs.

The invention is further illustrated with reference to the following examples and the accompanying figures. The following examples are offered by way of illustration and not by way of limitation.

### EXAMPLE 1

50 nm thick Fe catalyst thin films were deposited by RF sputtering on a Si(100) substrate in a Denton radio frequency (RF) magnetron sputtering machine at room temperature. Ion beam surface modification was performed in a Cameca IMS 6f secondary ion mass spectrometry (SIMS) system using 7.5 keV 02+beams at an incidence angle of 40.20 from a duoplasmatron ion gun. Grain sizes from 14.9 nm to 71.0 nm were observed. Analysis of the Fe film morphology is shown in Table 1.

TABLE 1
Morphology of Fe film at various sputter depths

| Sputter Depth | Roughness rms | Grain size |
|---|---|---|
| (nm) | (nm) | (nm) |
| 0 | 1.53 | 14.9 |
| 12 | 2.50 | 19.0 |
| 19 | 4.30 | 31.0 |
| 25 | 5.20 | 53.0 |
| 33 | 7.30 | 71.0 |

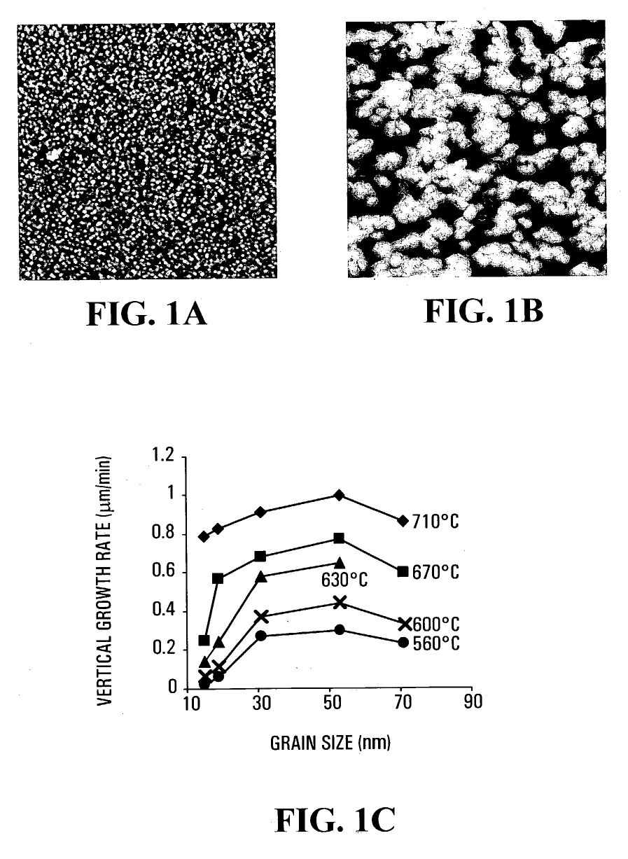

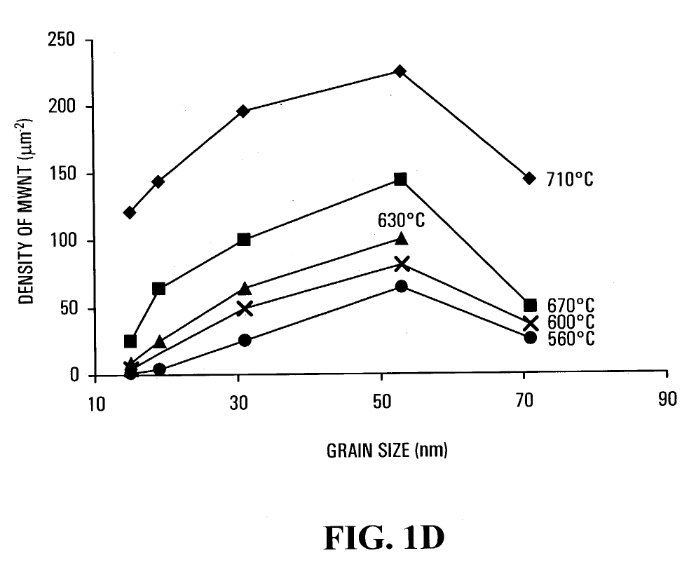

It can be seen that both roughness and grain size increase with sputter depth within the 50 nm Fe film thickness. FIG. 1(a) shows a 1 μm×1 μm AFM image of a 50 nm thick film of Fe prior to ion beam sputtering. FIG. 1(b) shows the film of FIG. 1(a) after O₂⁺ ion beam sputtering to a depth of 25 nm. The unmodified Fe surface has an average grain size of 15 nm. The AFM images of FIGS. 1(a) and (b) were obtained by using a Digital Instruments D3000 atomic force microscope in tapping mode.

The Fe coated substrates were then treated in a H₂ plasma for 10 minutes. Next, a mixture of acetylene (C₂H₂) and hydrogen (H₂) gases were introduced into the PECVD system at flow rates of 15 sccm and 60 sccm (standard cubic centimeter per second), achieving a chamber pressure of 1200 mTorr. The RF power was maintained at 100W and the growth time was kept constant at 10 minutes.

Aligned multiwall nanotubes of diameters between 30 to 40 nm were grown on the catalyst films using hot filament plasma enhanced chemical vapor deposition (HF-PECVD) in the temperature range of 560 to 710° C.

Graphical analysis of the relationship between vertical growth rate of carbon nanotubes against Fe catalyst film grain size at temperatures varying from 5600 to 710° C. is shown in FIG. 1(c). From the graph, it can be seen that modifying the catalyst surface affects the growth of the carbon nanotubes. This dependence on surface morphology is more pronounced at low temperatures. At every growth temperature, a good growth rate is attained at a grain size of about 50 nm.

Graphical analysis of the relationship between density of MWNT against Fe catalyst film grain size at temperatures varying from 5600 to 710° C. is shown in FIG. 1(d). From the graph, it can be seen that modifying the catalyst surface affects the density of carbon nanotubes grown. At every growth temperature, a good density is attained at a grain size of about 50 nm.

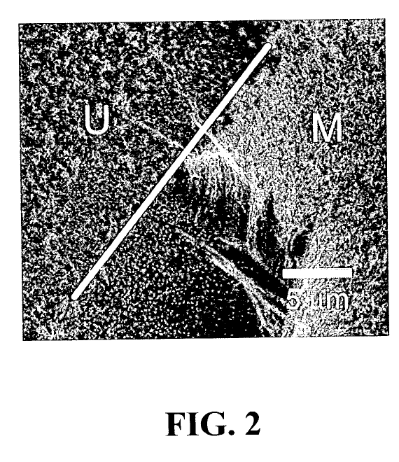

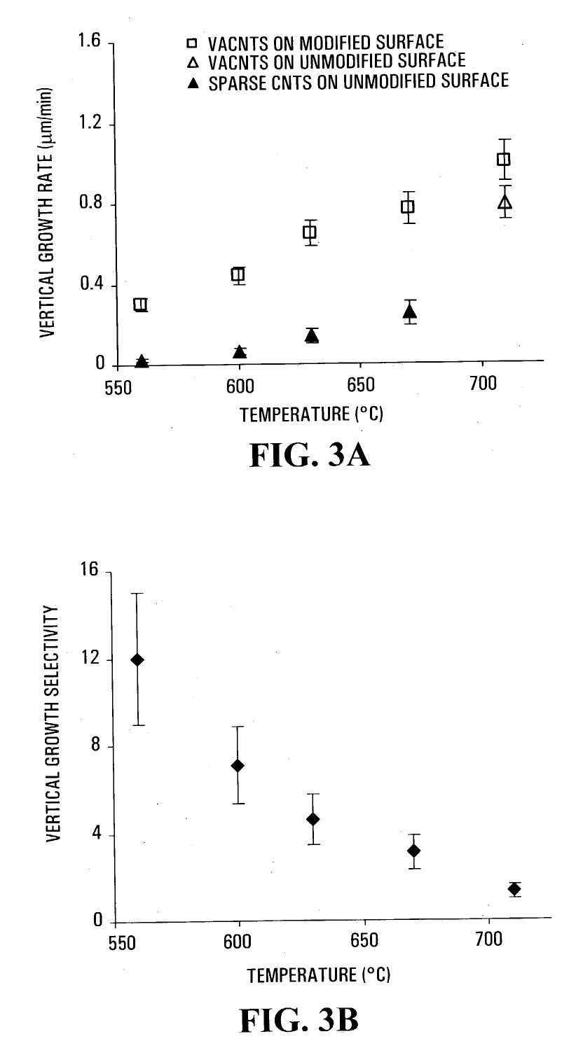

FIG. 2 shows a SEM image of carbon nanotubes grown at 630° C., imaged in the region of the boundary between ion modified and unmodified areas of the Fe catalyst film. The region labeled M shows aligned nanotubes (6.5 μm in length and 30 nm in width) grown on the ion modified surface, and the region labeled U shows only sparse nanotube growth on the unmodified surface. The dotted line drawn on the image delineates the boundary between these two regions. The lower region of the image had nanotubes removed by tweezers in order to view the vertical alignment of the nanotubes. FIG. 3(a) shows a plot of the vertical growth rate of nanotubes on ion modified (after sputtering to 25 nm optimal depth) and unmodified surfaces as a function of growth temperature. “VACNT” stands for “vertically aligned carbon nanotubes” and “CNT” stands for “carbon nanotubes”. As the growth temperature increases, a corresponding increase in growth rate is observed. However, the growth rate on the unmodified surface is significantly lower and the nanotubes are sparsely formed on the surface except at higher temperatures. At 560° C., negligible growth of random nanotubes was observed on the unmodified catalyst surface. At 670° C., the nanotubes are still randomly oriented although dense growth is observed. At 710° C., dense and vertically aligned nanotubes are observed. On the ion modified surface however, the nanotubes are aligned and dense even at 560° C., with the growth rate increasing at higher temperatures. The data of FIG. 3(a) are presented in terms of vertical growth selectivity in FIG. 3(b). The selectivity values are determined by calculating the ratio of the vertical growth rate between the modified and unmodified surfaces. The highest selectivity is observed to be at 560° C. This is because there is negligible nanotube growth on the unmodified surface. Below this temperature, the nanotubes grown on the ion modified surface are less well aligned (sparse). Although the selectivity is highest at lower growth temperatures, the quality and growth rate of the aligned nanotubes increases with growth temperature. Hence, an optimum growth temperature giving good growth rate and selectivity of well-aligned nanotubes can be chosen for specific device applications.

### EXAMPLE 2

This example describes a control experiment done to elucidate the role of H₂ plasma.

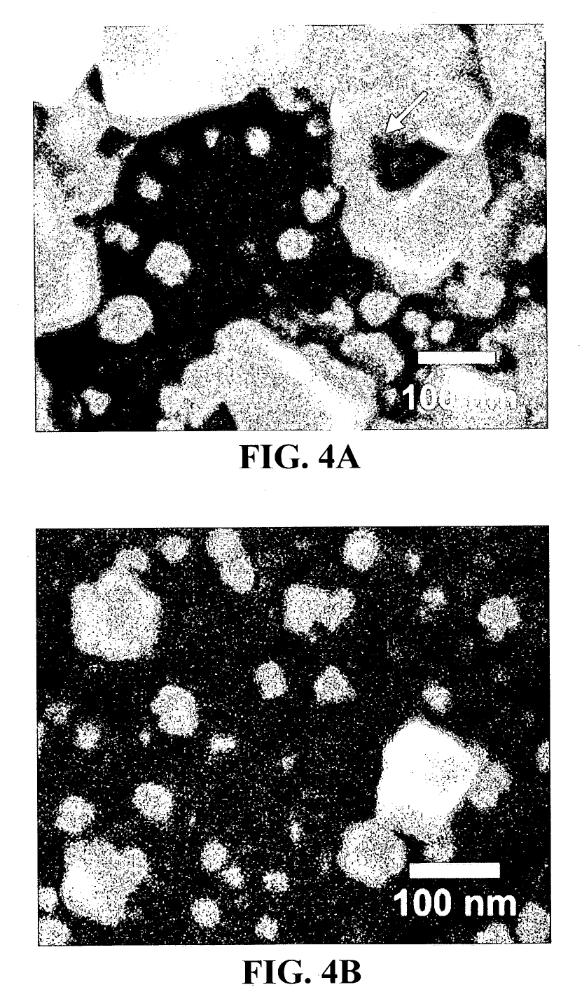

Fe-coated substrates were treated in a H₂ plasma for 10 minutes at 710° C. FIG. 4(a) is an SEM image of an Fe surface (“unmodified surface”) after the H₂ plasma treatment. FIG. 4(b) is an SEM image of an Fe surface, modified by ion beam at a sputter depth 25 nm (“modified surface”) and then treated with the H₂ plasma. Graphitic sheets were observed mainly on the unmodified surface, as shown by the arrow. Without being bound by any theory it is believed that the graphite sheets form as a result of trace amounts of residual carbon in the chamber dedicated to carbon nanotube growth. The observation of carbon deposition during the H₂ treatment process is believed to be an accurate reflection of what actually occurs during the routine growth process. Experiments suggest that the unmodified surface with high packing density of small Fe catalyst grains (and hence overall smoother morphology) promotes the deposition of graphitic sheets at the initial nanotube growth step. The presence of these graphitic sheets poisons the Fe catalyst and inhibits subsequent MWNT nucleation.

Aligned MWNTs were grown by decomposition of acetylene (15 sccm) in the presence of hydrogen (60 sccm) at 720° C. on the H₂ treated surfaces and imaged in a JSM JEOL 6430F field emission scanning electron microscope (FE-SEM). The modified surface showed a high growth rate. On the modified surface it was observed that the diameters of the carbon nanotubes synthesized were independent of the initial Fe catalyst grain sizes, most of the MWNTs having diameters in the range of 30 to 40 nm. On the unmodified surface, random carbon nanotube growth was observed.

H₂ plasma etching done just before nanotube growth appears to modify the catalyst grains to a size range of 30 to 40 nm. The high growth rate of carbon nanotubes on the modified surface may be explained by the modified surface having the optimum grain size and packing density for carbon nanotube growth. However, H₂ plasma treatment alone was not observed to obtain a higher growth rate. Without being bound by any theory, grain packing density, which appears to be influenced by the first step of surface modification (ion or laser), rather than carbon deposition appears to have a greater influence on growth rate.

### EXAMPLE 3

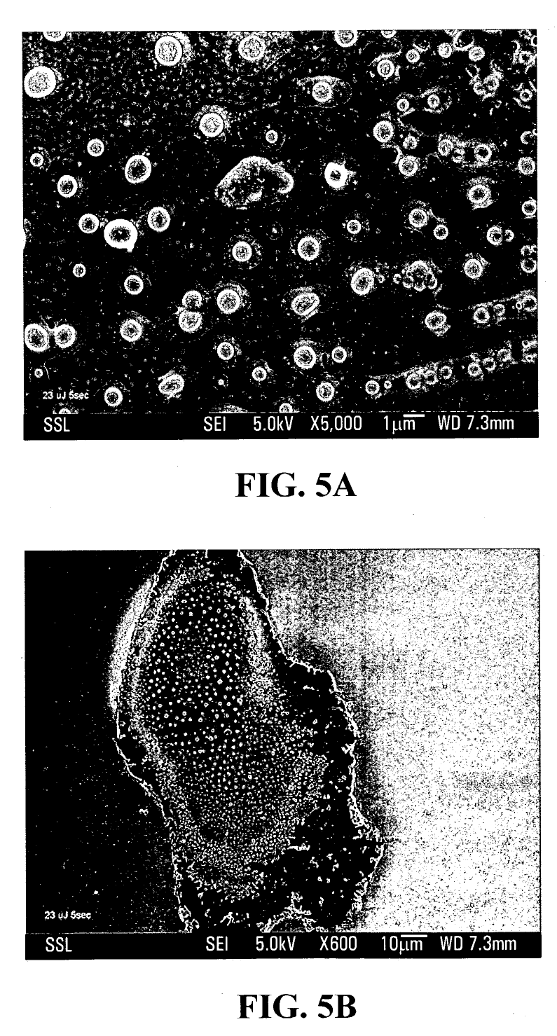

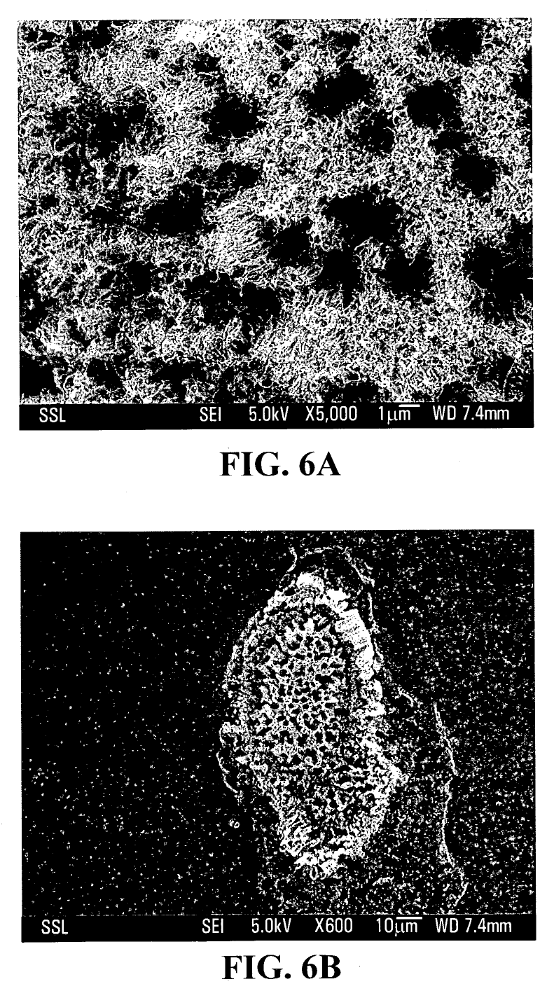

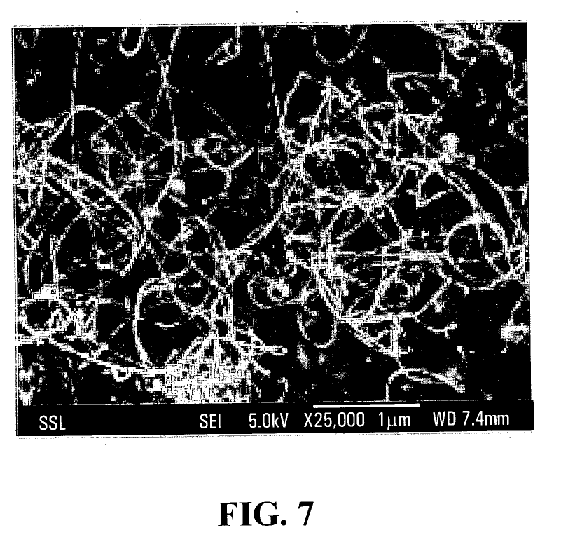

A 50 nm Fe catalytic thin film was modified using nanosecond optical pulses from a Q-switched, frequency-doubled Nd:YAG laser (Spectra Physics DCR3) with pulse duration of 7 ns (equal on and off times); the total laser duration was 5 s. The laser irradiance was 0.17 GW/cm² over an area of a few tenths of μm. The subsequent carbon nanotube growth time was approximately 10 minutes, with a growth temperature of approximately 630° C. FIGS. 5(a) and (b) show SEM images of the modified Fe surface at magnifications of 5000× and 600× respectively. Carbon nanotubes grown on this surface are shown in FIGS. 6(a) and (b), which are SEM images at magnifications of 5000× and 600× respectively. As is particularly shown in FIG. 6(b), dense carbon nanotubes are grown on the laser modified surface. This must be contrasted with carbon nanotubes grown at a temperature of 630° C. on a surface that was not so modified as shown in FIG. 7, which is an SEM image at a magnification of 5000×. It can be seen that nanotube growth is random and sparse.

Although the foregoing invention has been described in some detail by way of illustration and example for purposes of clarity of understanding, it is readily apparent to those of ordinary skill in the art in light of the teachings of this invention that certain changes and modifications may be made thereto without departing from the spirit or scope of the appended claims.

1. A method for making a catalyst for use in the preparation of carbon nanotubes, which method comprises subjecting a surface of a thin film of a catalytic metal on a support to selective mechanical or electromagnetic modification to enhance the grain size of the metal at the surface.

2. The method according to claim 1, wherein the selective mechanical or electromagnetic modification is made to the thin film of the catalytic metal to obtain modification in a predetermined pattern.

3. The method according to claim 1, wherein the modification is done by ionic bombardment.

4. The method according to claim 1, wherein the modification is done by laser.

5. The method according to claim 1, wherein the thin film is modified to a depth of from about 10 nm to about 40 nm.

6. The method according to claim 1, wherein the thin film is modified to a depth of about 25 nm.

7. The method according to claim 1, wherein the grain size of the metal at the surface, after the modification is from about 15 nm to about 70 nm.

8. The method according to claim 1, wherein the grain size of the metal at the surface, after the modification is about 53 nm.

9. The method according to claim 1, wherein the thin film comprises Fe, Ni, Co or mixtures thereof, and the film has a thickness of from about 50 to about 500 nm.

10. The method according to claim 1, wherein the mechanical modification is carried out with an ion beam with an energy of from about 1 to about 30 keV.

11. The method according to claim 10, wherein the ion beam comprises an ion species selected from the group consisting of O₂⁺, liquid metal ions and noble gas ions.

12. The method according to claim 1, wherein the mechanical modification is carried out with an O₂⁺ ion beam with an energy of about 7.5 keV.

13. The method according to claim 1, wherein the thin film is treated with a reducing plasma following the mechanical or electromagnetic modification.

14. The method according to claim 1, wherein the thin film is modified to have a grain size of from about 14.9 nm to about 71.0 nm, and a surface roughness of from about 1.53 nm to about 7.30 nm.

15. A process for the selective area growth of carbon nanotubes on a substrate which bears a catalyst thin film, the process comprising contacting the catalyst made according to the method of claim 1 with a carbon source under pressure and temperature conditions which promote carbon nanotube synthesis.

16. The process according to claim 15, wherein the catalyst and the carbon source are contacted at a temperature greater than 500° C.

17. The process according to claim 15, wherein the catalyst and the carbon source are contacted at a temperature of from about 560° C. to about 710° C.

18. The process according to claim 15, wherein the carbon source is a hydrocarbon.

19. The process according to claim 18, wherein the hydrocarbon is selected from methane, ethene and acetylene.

20. The process according to claim 15, wherein the carbon-nanotubes are aligned multi-walled carbon nanotubes.

21. The process according to claim 20, wherein the aligned multi-walled carbon nanotubes are grown in a predetermined pattern.

22. Use of the carbon nanotubes made according to the process of claim 15, for the manufacture of display, electronic and microelectromechanical devices.

23. Use according to claim 22, wherein the display device is a field emission display device.
